(19) United States
(12) Patent Application Publication
(10) Pub. No.: US 2024/0178165 A1
(43) Pub. Date: May 30, 2024

(54) STRUCTURE WITH COPPER BOND PAD AND COPPER INTERCONNECT

(71) Applicant: GlobalFoundries Singapore Pte. Ltd., Singapore (SG)

(72) Inventors: Ranjan Rajoo, Singapore (SG); Kai Chong Chan, Singapore (SG)

(21) Appl. No.: 18/058,932

(22) Filed: Nov. 28, 2022

(51) Int. Cl. H01L 23/00

(52) U.S. Cl. CPC H01L 24/05; H01L 24/45; H01L 24/13; H01L 2224/0239; H01L 2224/0381; H01L 2224/0401; H01L 2224/04042; H01L 2224/05073; H01L 2224/05082; H01L 2224/05147; H01L 2224/05164; H01L 2224/05573; H01L 2224/05647; H01L 2224/05664; H01L 2224/13111; H01L 2224/13139; H01L 2224/13147; H01L 2224/45147

(57) ABSTRACT

A structure includes a copper bond pad for copper interconnects that uses a conductive layer of palladium or copper palladium. The structure may include a substrate, and a copper bond pad over the substrate. A conductive layer is in direct contact with an upper surface of the copper bond pad. The conductive layer consists of palladium, copper palladium or both palladium and copper palladium. A copper interconnect is in direct contact with the conductive layer. The copper interconnect can be a copper wire bond or a copper redistribution layer (RDL) with a solder ball on the copper RDL. The structure provides high temperature reliability copper-to-copper interconnection by removing intermetallic compounds between the pad and copper interconnect.

### BACKGROUND

The present disclosure relates to semiconductor device structures and, more particularly, to a structure including a copper bond pad with copper interconnects that uses a conductive layer of palladium or copper palladium.

In semiconductor device fabrication, various layers of insulating material, semiconducting material and conducting material are patterned to create features that form integrated circuit (IC) devices, such as transistors, capacitors and resistors. These IC devices are interconnected to achieve their intended function, thereby forming an integrated circuit (IC) chip. The IC chip will additionally include bond pads for forming interconnections with external packaging components; for example, a printed circuit board through wire bonding or flip-chip bonding. Bond pads are typically made from a conductive material, such as copper (Cu).

After the IC devices are fabricated, use of copper interconnects to couple to the copper bond pads is preferred because it eliminates undesirable intermetallic layers between the pads and interconnects, and allows use of existing packaging materials, i.e., copper wire bonds. Copper interconnects are also preferred because they eliminate use of other more costly materials such as gold, silver and aluminum.

One of the challenges in using copper bond pads is preventing oxidation that can lead to product failure, such as moisture penetration or galvanic corrosion. Oxidation can occur where the copper in the copper bond pad is exposed during, for example, packaging, transportation, storage, or wafer sorting, etc. Passivation layers may be formed on the IC devices to protect the copper bond pads and other chip surfaces from oxidation, mechanical damage and to prevent moisture build-up and penetration into the IC devices. However, use of passivation layers leads to other challenges. With regard to oxidation, the passivation layers must be removed over the copper bond pads to couple wire bonds or solder bumps to the pad, so the passivation layers do not necessarily prevent all oxidation on the copper bond pads. In addition, the mechanisms used to remove the passivation layers from over the copper bond pads may not fully remove the passivation layer(s) or may leave residual materials from the etching chemistry (e.g., adhesive-like contaminants, such as fluorine polymers) that can lead to reliability issues.

### SUMMARY

All aspects, examples and features mentioned below can be combined in any technically possible way.

An aspect of the disclosure provides a structure, comprising: a substrate; a copper bond pad over the substrate; a conductive layer in direct contact with an upper surface of the copper bond pad, the conductive layer consisting of palladium, copper palladium or both palladium and copper palladium; and a copper interconnect in direct contact with the conductive layer.

An aspect of the disclosure provides a method comprising: exposing an upper surface of a copper bond pad; forming a conductive layer directly on the exposed upper surface of the copper bond pad, the conductive layer consisting of palladium; and forming a copper interconnect directly on the conductive layer.

An aspect of the disclosure provides a method comprising: exposing an upper surface of a copper bond pad at a bottom of an opening defined in at least one dielectric layer, wherein a passivation layer is on sidewalls of the opening above the copper bond pad; forming a conductive layer directly on the exposed upper surface of the copper bond pad, the conductive layer consisting of palladium; and forming a copper interconnect directly on the conductive layer.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIGS. 1A-C show cross-sectional views of structures according to embodiments of the disclosure;

FIGS. 2A-C show cross-sectional views of structures according to other embodiments of the disclosure;

FIGS. 3A-C show cross-sectional views of structures according to yet other embodiments of the disclosure;

FIGS. 4-7 show cross-sectionals view of part of a method according to other embodiments of the disclosure; and

FIGS. 8-12 show cross-sectional views of part of a method according to other embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected,” “in direct contact with” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure including a copper bond pad for copper interconnects that uses a conductive layer of palladium, copper palladium or both, and related methods. The structure may include a substrate, and a copper bond pad over the substrate. A conductive layer is in direct contact with an upper surface of the copper bond pad. The conductive layer consists only of palladium, copper palladium or both palladium and copper palladium. A copper interconnect is in direct contact with the conductive layer. The copper interconnect can be a copper wire bond or a copper redistribution layer (RDL), the latter perhaps with a solder ball on the copper RDL. The structure provides high temperature reliability by removing intermetallic compounds between the copper bond pad and copper interconnect. The structure lowers costs because it does not require more expensive materials, like gold, silver or aluminum materials. The process of making the structure is maskless and does not require any new equipment. The structure can be used at any first level interconnection, e.g., wire bond, flip chip or copper pillar.

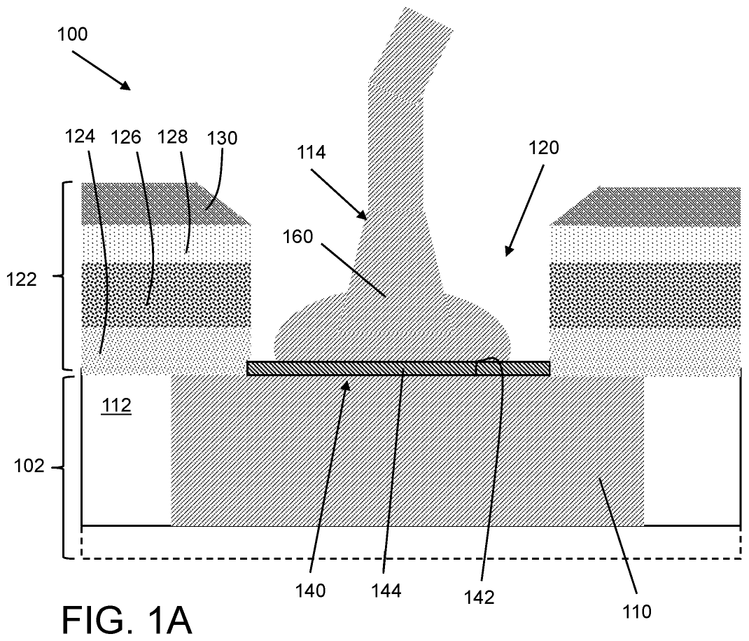

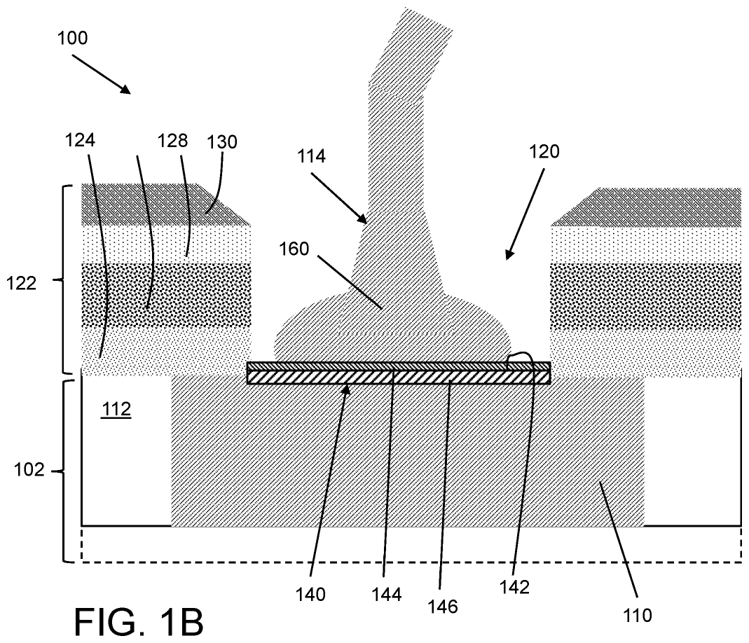

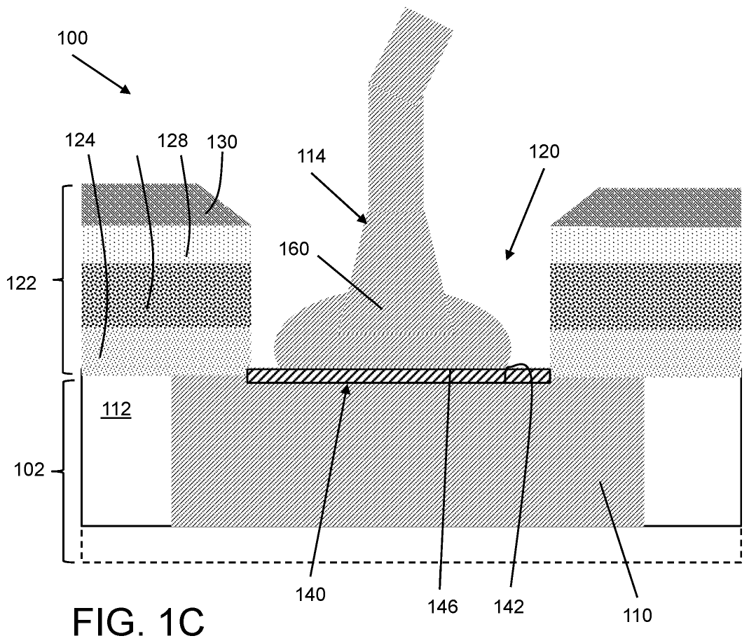

FIGS. 1A-C show cross-sectional views of a structure 100 according to embodiments of the disclosure. Structure 100 includes a substrate 102 (FIGS. 1A-3B only for clarity). Substrate 102 can include any back-end-of-line (BEOL) interconnect layers (schematically illustrated by dashed box in FIGS. 1A-3B) used to scale up from semiconductor devices in lowermost layer(s) (not shown) of the integrated circuit (IC) chip. Substrate 102 may include layers of dielectric including metal wires and vias (not shown) electrically interconnecting the other IC devices in the IC chip, e.g., transistors, capacitors, resistors, etc.

Embodiments of structure 100 include a copper bond pad 110 over substrate 102. Copper bond pad 110 (hereafter “pad 110”) may be in or close to a last dielectric layer 112 of substrate 102 at which external copper interconnects 114 couple to copper bond pad 110. Pad 110 can be formed in substrate 102 using any now known or later developed semiconductor fabrication techniques, e.g., patterning a mask, etching an opening in last dielectric layer 104, depositing copper and planarizing. Pad 110 is defined at a bottom of an opening 120 in at least one dielectric layer 122 over substrate 102. Dielectric layer(s) 122 electrically isolate pad 110 and other conductive parts in last dielectric layer 112 from external interconnects 114, protect pad 110 and other chip surfaces from oxidation and mechanical damage, and prevent moisture build-up and penetration into the IC devices. In the non-limiting example shown, dielectric layer(s) 122 are shown to include a silicon carbonitride (SiCN) layer 124, an oxide layer 126 (e.g., tetraethyl orthosilicate, Si(OC₂H₅)₄ (TEOS) oxide), a silicon nitride layer 128, and a photosensitive polyimide (PSPI) layer 130. It is emphasized that the list of dielectric layer(s) 122 is only illustrative and not limiting as a wide variety alternative dielectric layer(s) are possible. In addition, the various thicknesses of layer(s) 122 are not to scale.

FIGS. 2A-C show cross-sectional views of a structure 100 according to other embodiments of the disclosure. In FIGS. 2A-C, structure 100 may also include a passivation layer 150 on sidewalls 152 of dielectric layer(s) 122 (defined by opening 120) above pad 110. Passivation layer 150 may include any now known or later developed layer of passivation material(s) provided over pad 110 to protect pad 110 and other chip surfaces from oxidation, mechanical damage and to prevent moisture build-up and penetration into the IC devices. In one non-limiting example, passivation layer 150 may include a nitrogen-doped barrier low-k (SiCN) layer, silicon nitride (Si₃N₄), an oxide such as silicon oxide (SiO₂) or tetraethyl orthosilicate, Si(OC₂H₅)₄ (TEOS) based silicon oxide (SiO₂).

Other layer(s) are also possible. As shown in FIGS. 2A-C, and as will be further described, passivation layer 150 is removed from an upper surface 142 of pad 110 before forming copper interconnect 114, and thus remains only on sidewalls 152 of opening 120.

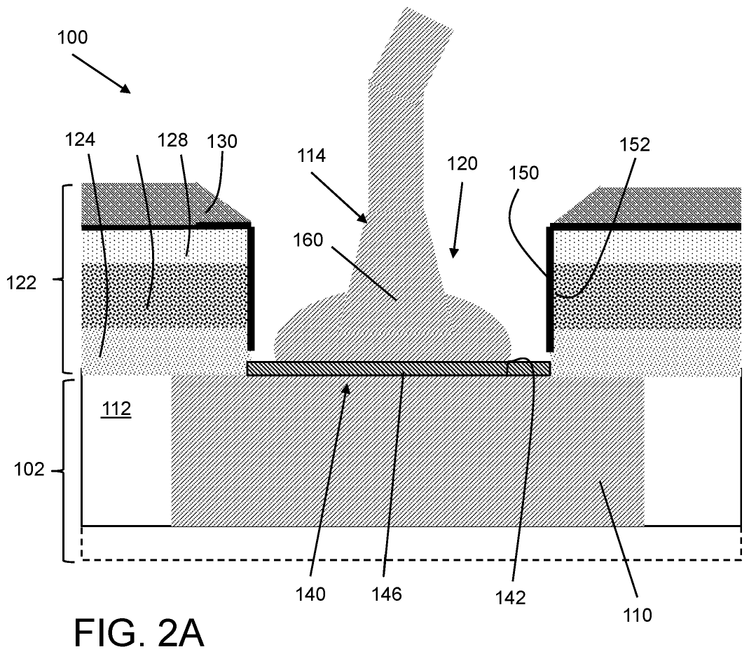

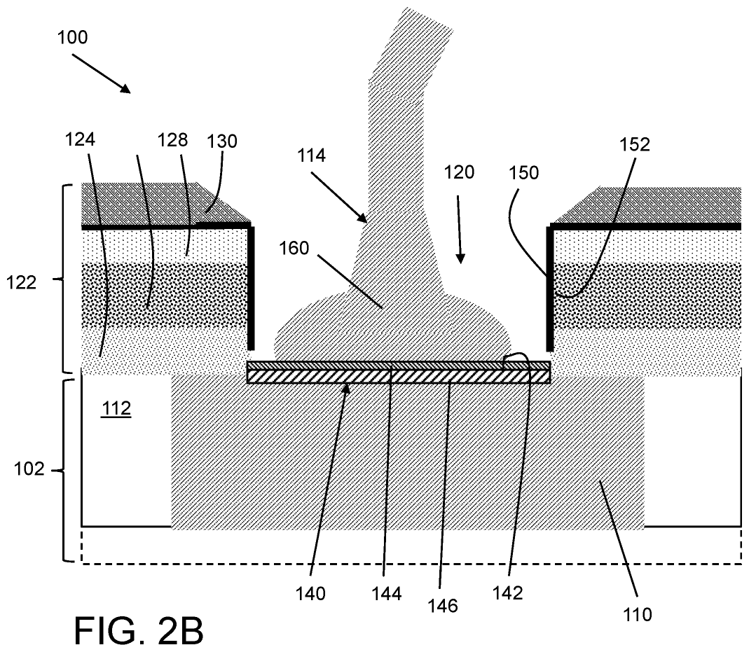

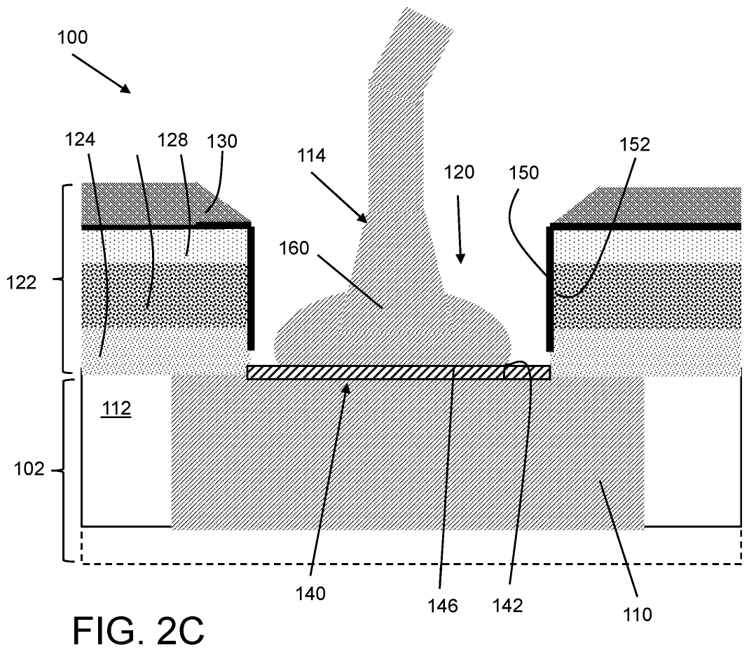

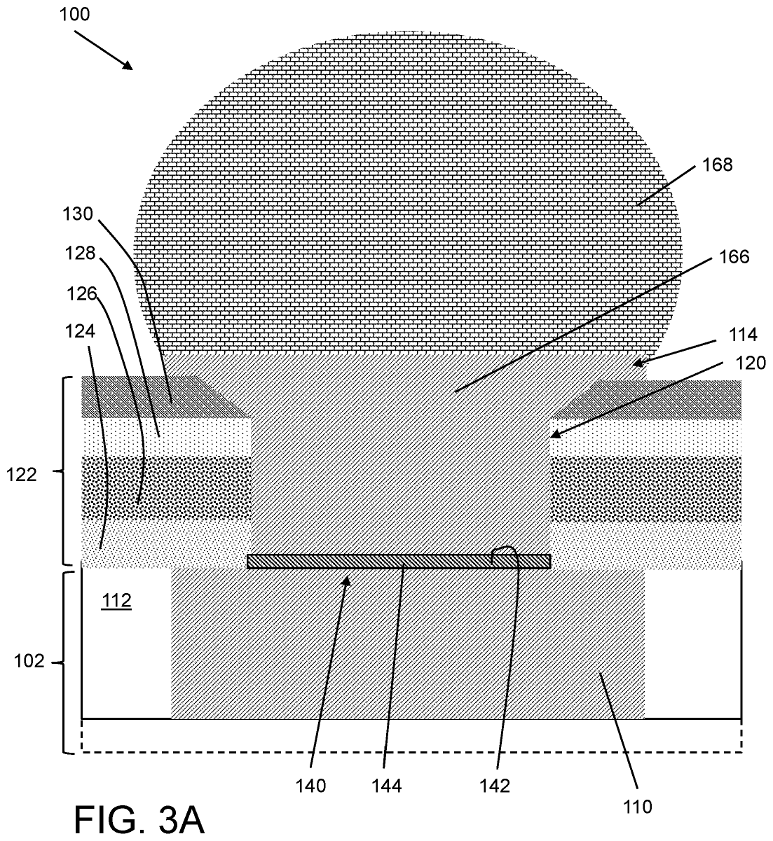

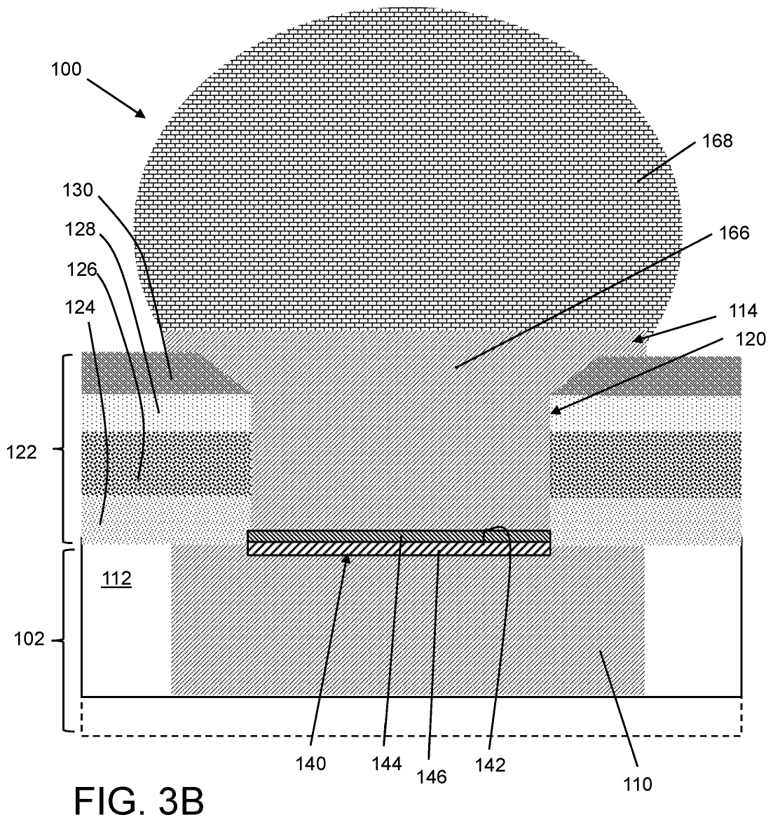

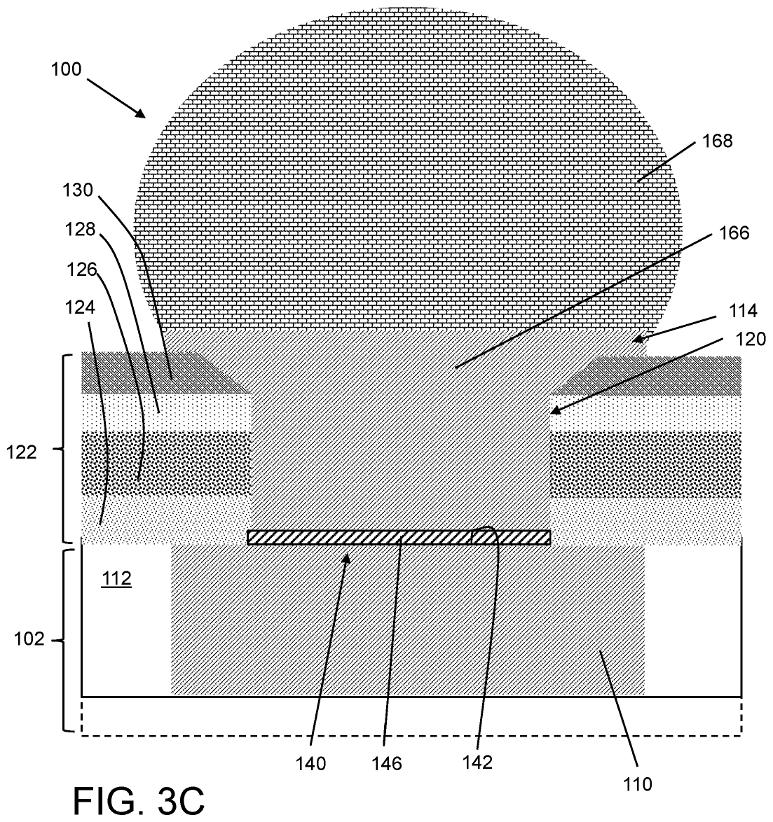

FIGS. 3A-C show cross-sectional views of a structure 100 according to yet other embodiments of the disclosure. As will be described further, rather than a wire bond 160 (FIGS. 1A-C, 2A-C), FIGS. 3A-C show copper interconnect 114 including a copper redistribution layer (RDL) 166 in direct contact with conductive layer 140, and perhaps a solder ball 168 on copper RDL 166.

In any of the embodiments, structure 100 includes a conductive layer 140 in direct contact with upper surface 142 of pad 110. Conductive layer 140 includes only palladium, copper palladium or both palladium and copper palladium. Conductive layer 140 may have a thickness of 15 to 100 nanometers (nm), and hence is a relatively thin layer. In comparison, pad 100 may have a thickness of 100000 nm. (Note, drawings are not to scale.) In FIGS. 1A, 2A and 3A, conductive layer 140 includes just a palladium layer 144, i.e., between pad 110 and copper interconnect 114. In FIGS. 1B, 2B and 3B, conductive layer 140 includes layers of both palladium 144 and copper palladium 146. In FIGS. 1C, 2C and 3C, conductive layer 140 includes just copper palladium 146. As will be described further herein, conductive layer 140 initially includes just palladium layer 144. However, the thickness of palladium layer 144 is such that it may at least partially diffuse into the copper of pad 110 or the copper of copper interconnect 114 thereover such that there is, as shown in FIGS. 1B, 2B and 3B, a palladium layer 144 and a copper palladium layer 146, or as shown in FIGS. 1C, 2C and 3C, only just a copper palladium layer 146. For illustration purposes in FIGS. 1B, 2B and 3B, copper palladium layer 146 is shown below palladium layer 144, but it may also be above palladium layer 144 or both above and below. Regardless, there are no other intervening layers with different materials than palladium and copper between conductive layer 140 and pad 110. That is, only conductive layer 140 is between copper interconnect 114 and pad 110. Conductive layer 140 extends across an entire upper surface 142 of pad 100, i.e., there are no other layers or elements contacting upper surface 142.

As noted, structure 100 also includes copper interconnect 114 in direct contact with conductive layer 140. In FIGS. 1A-C and 2A-C, copper interconnect 114 includes a copper wire bond 160 in direct contact with conductive layer 140. In another embodiment, shown in FIGS. 3A-C, copper interconnect 114 includes copper RDL 166 in direct contact with conductive layer 140, and perhaps solder ball 168 on copper RDL 166. As known in the art, an RDL includes an extra metal layer on an IC chip that makes pads 110 available in other locations on the IC chip for better access. RDL 166 may route to a variety of locations on the IC chip. Where solder ball 168 is also present, it may be used as part of a flip chip or copper pillar packaging assembly in a known fashion.

Conductive layer 140 including palladium removes the need for common intermetallic layers that are typically necessary for adhesion to pad 110 and/or seeding/activation purposes. Conductive layer 140 including palladium also provides a surface having a hardness, e.g., around 120 MegaPascals, conducive to a reliable bonding to copper bond pad 110, allowing for copper-to-copper wire bonds 160 and copper-to-copper RDLs 166. Palladium is also advantageous because it has low resistance, is inert (does not oxidize), is readily available, and is easily incorporated into semiconductor fabrication processes.

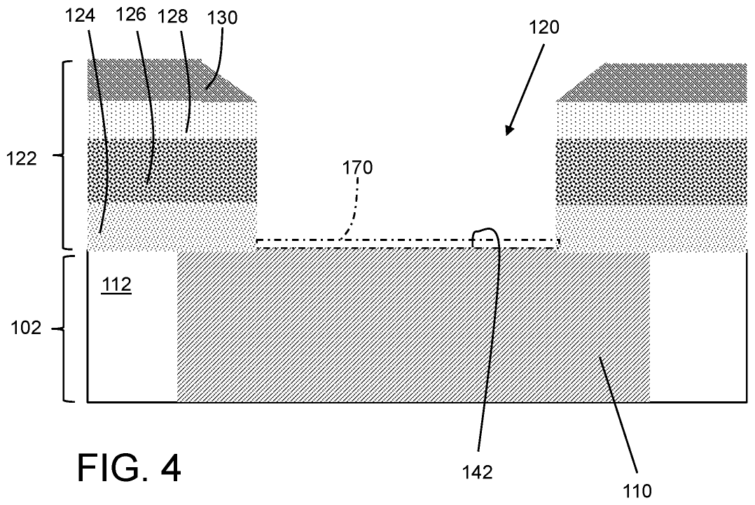

FIGS. 4-7 show cross-sectionals view of part of a method of forming structure 100 according to embodiments of the disclosure. FIG. 4 shows an embodiment in which structure 100 is formed using any now know later developed semiconductor fabrication techniques up to formation of copper interconnects 114 (FIGS. 1A-3B). In FIGS. 4-7, pad 110 is provided in an exposed manner with no passivation layer 150 protecting it from being oxidized. In this case, opening 120 has been formed through dielectric layer(s) 122 and an oxide layer 170, i.e., copper oxide, has (naturally) formed on upper surface 142 of pad 110.

FIG. 4 shows removing oxide layer 170, i.e., copper oxide, (dashed box) to expose upper surface 142 of pad 110, i.e., the copper of pad 110. The removal process may include performing any appropriate plasma-based etching such as but not limited to: exposure to a plasma, cleaning, rinsing, etching such as a reactive ion etching (RIE) to remove oxide layer 170, rinsing, etc.

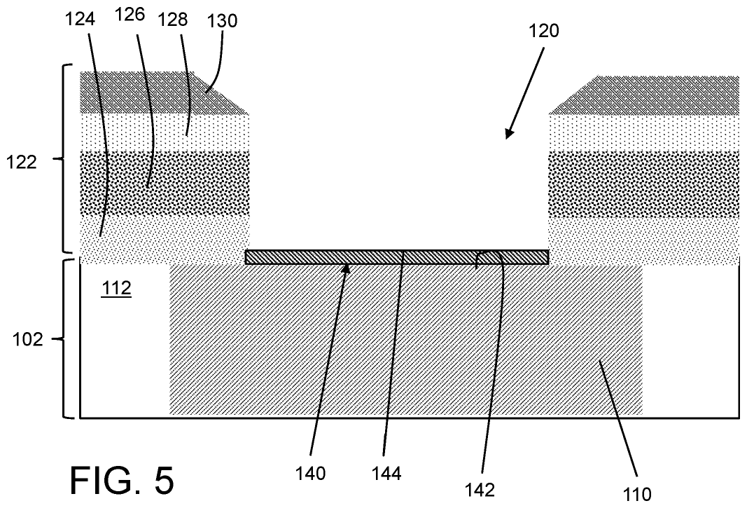

FIG. 5 shows forming conductive layer 140 directly on exposed upper surface 142 of pad 110. As noted, conductive layer 140 initially consists of only palladium. Conductive layer 140 may be formed, for example, by electroless depositing of palladium layer 144. Conductive layer 140 may have a thickness of 15 to 100 nm, and hence is a relatively thin layer.

In one embodiment, conductive layer 140 remains only palladium layer 144. That is, palladium layer 144 does not diffuse into the copper of pad 110. In this case, the method may include, as shown in FIGS. 1A and 3A, forming copper interconnect 114 directly on conductive layer 140 of palladium. This step may include, for example, cleaning conductive layer 140 prior to forming copper interconnect 114. The cleaning may include, for example, performing a plasma etch using an etch chemistry including hydrogen in a ratio of 5% to 10% and a remaining portion including one of argon and nitrogen. Other cleaning processes may also be applicable. In FIGS. 1A, copper interconnect 114 forming includes forming a copper wire bond 160 on conductive layer 140. Copper wire bond 160 may be formed using any now known or later developed wire bonding process, e.g., copper wire bonding in a forming gas such as a mixture hydrogen and nitrogen (H₂N₂) or another inert gas. In FIG. 3A, forming copper interconnect 114 includes forming a copper RDL 166 and (optionally) solder ball 168 on copper RDL 166. Forming copper RDL 166 may include, for example, forming a titanium copper alloy seed layer (not shown), and electroplating to form copper RDL 166. Solder ball 168 may be formed using any now known or later developed process of forming solder balls 168. Solder balls 168 may include any appropriate solder alloy, such as but not limited to tin silver or tin silver copper.

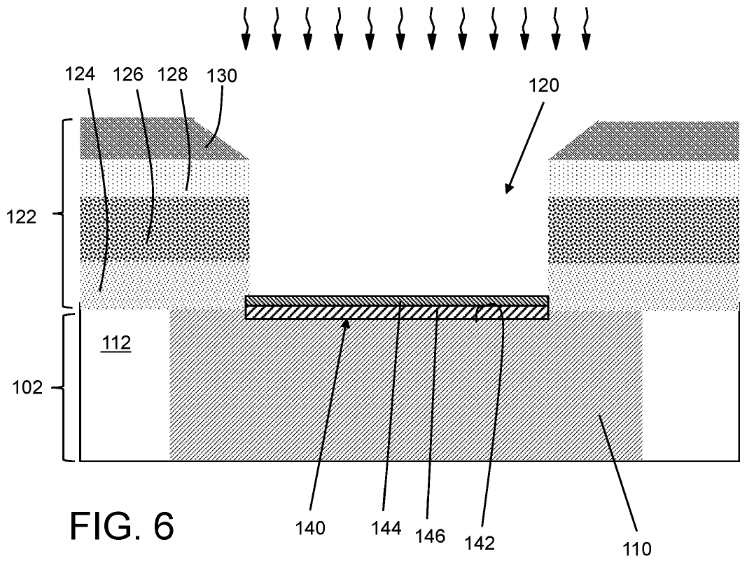

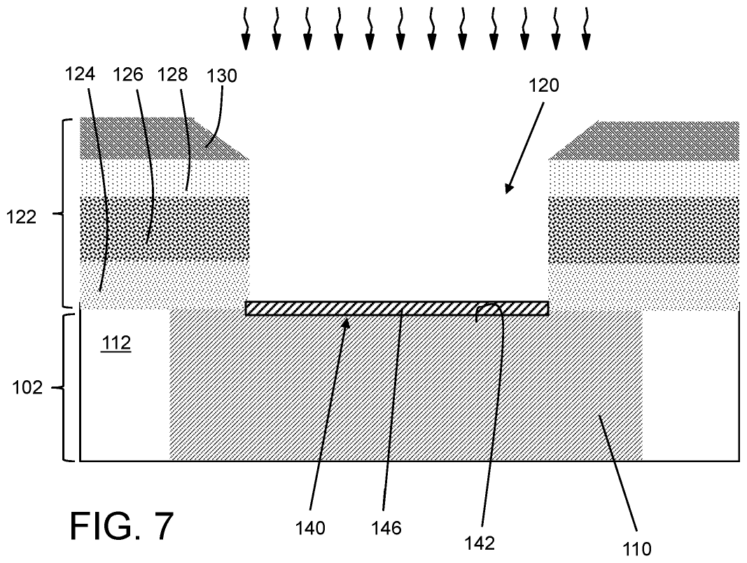

Referring to FIG. 6, in another embodiment, at least a portion of palladium layer 144 may diffuse into the copper of pad 110 to convert conductive layer 140 to include palladium layer 144 and copper palladium layer 146 (below palladium layer 144). This process may occur naturally due to the thinness of palladium layer 144. Alternatively, as also shown in FIG. 6, an annealing (i.e., heat treating—see curvy arrows) process may be performed after (initially) forming conductive layer 140. The annealing converts at least a portion of (initial) conductive layer 140 from palladium to a copper palladium alloy. FIG. 7 shows an embodiment in which all or mostly all of palladium layer 144 diffuses into the copper of pad 110 to convert conductive layer 140 to copper palladium layer 146. This process may occur naturally or through the annealing process. In FIGS. 6 and 7, it will be noted that the position of upper surface 142 of pad 110 may shift downwardly depending on the amount of diffusion.

FIGS. 1B and 3B show forming copper interconnect 114 directly on conductive layer 140 that now includes palladium layer 144 and copper palladium layer 146. This process can include the same processes as described relative to FIGS. 1A and 3A. FIGS. 1C and 3C show forming copper interconnect 114 directly on conductive layer 140 that now includes only copper palladium layer 146. This process can include the same processes as described relative to FIGS. 1C and 3C.

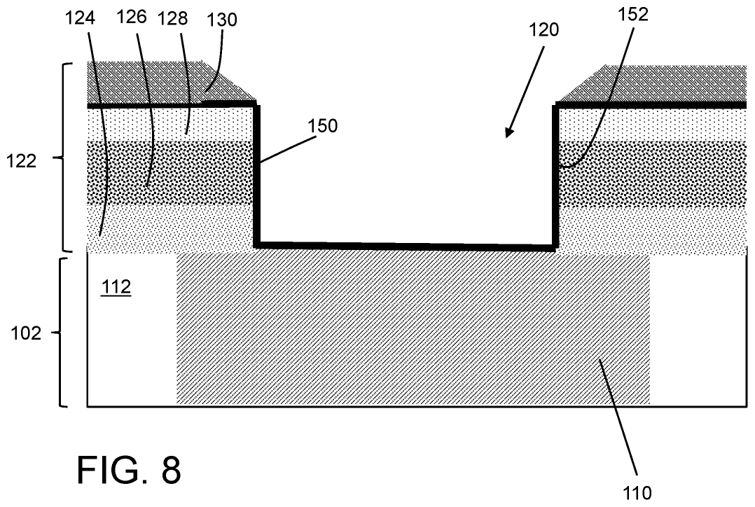

FIGS. 8-12 show cross-sectional views of part of a method according to other embodiments of the disclosure. FIG. 8 shows an embodiment in which structure 100 is formed using any now know later developed semiconductor fabrication techniques up to formation of copper interconnects 114 (FIGS. 1A-3B). In FIGS. 8-12, in contrast to FIGS. 4-7, pad 110 initially has passivation layer 150 thereover protecting it and other structure from being oxidized. Here, opening 120 has been formed through dielectric layer(s) 122, e.g., layers 124, 126, 128, and passivation layer 150, e.g., SiCN, has been formed in opening 120 and over a surface of dielectric layer 128. Layer 130 of dielectric layer(s) 122 is shown over passivation layer 150. Passivation layer 150 may be formed by any appropriate deposition technique for the material used, e.g., chemical vapor deposition.

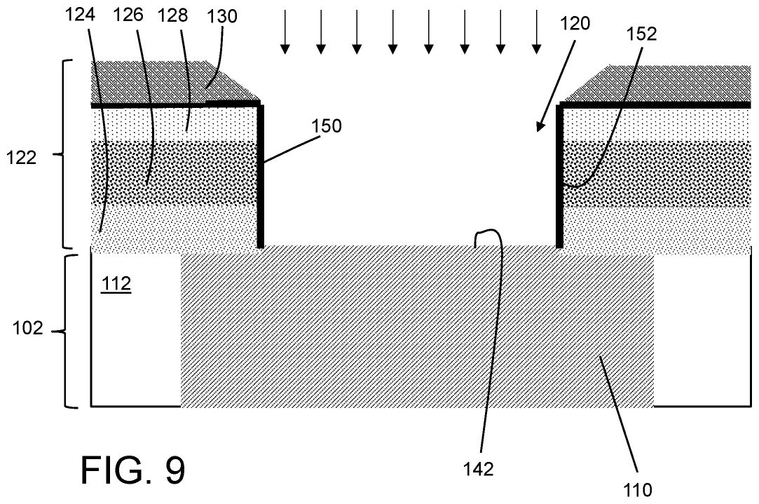

FIG. 9 shows exposing upper surface 142 of pad 110 at a bottom of opening 120 defined in dielectric layer(s) 122. Passivation layer 150 remains on sidewalls 152 of opening 120 above pad 110. The exposing includes removing passivation layer 150, e.g., SiCN, to expose upper surface 142 of pad 110, i.e., the copper of pad 110. The removal process may include performing any appropriate plasma-based etching such as but not limited to: exposure to a plasma, cleaning, rinsing, etching such as a reactive ion etching (RIE) to remove passivation layer 150, rinsing, etc. As noted, passivation layer 150 may remain on sidewalls 152 of opening 120 to protect those dielectric layer(s) 122 thereunder.

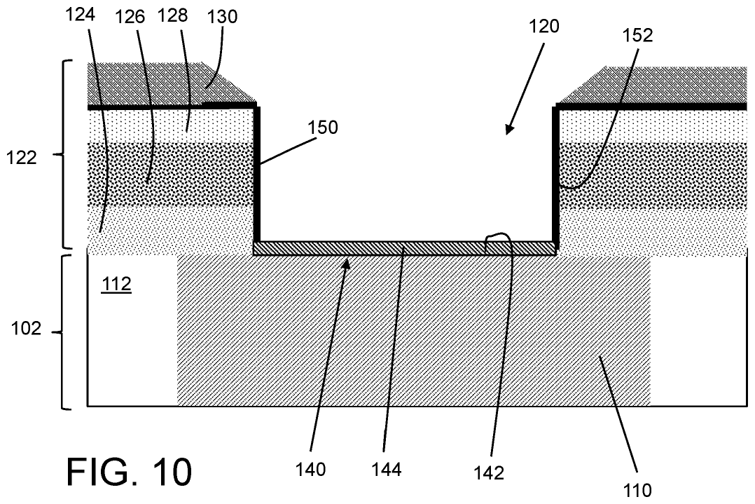

FIG. 10 shows forming conductive layer 140 directly on exposed upper surface 142 of pad 110. As noted, conductive layer 140 initially consists of only palladium. Conductive layer 140 may be formed, for example, by electroless depositing of palladium layer 144. Conductive layer 140 may have a thickness of 15 to 100 nm, and hence is a relatively thin layer.

In one embodiment, conductive layer 140 remains only palladium layer 144. That is, palladium layer 144 does not diffuse into the copper of pad 110. In this case, the method may include, as shown in FIG. 2A, forming copper interconnect 114 directly on conductive layer 140 of palladium, and with passivation layer 150 on sidewalls 152 of opening 120. This step may include, for example, cleaning conductive layer 140 prior to forming copper interconnect 114. The cleaning may include, for example, performing a plasma etch using an etch chemistry including hydrogen in a ratio of 5% to 10% and a remaining portion including one of argon and nitrogen. Other cleaning processes may also be applicable. In FIG. 2A, copper interconnect 114 forming includes forming copper wire bond 160 on conductive layer 140. Copper wire bond 160 may be formed using any now known or later developed wire bonding process, e.g., copper wire bonding in a forming gas such as a mixture hydrogen and nitrogen (H₂N₂) or another inert gas.

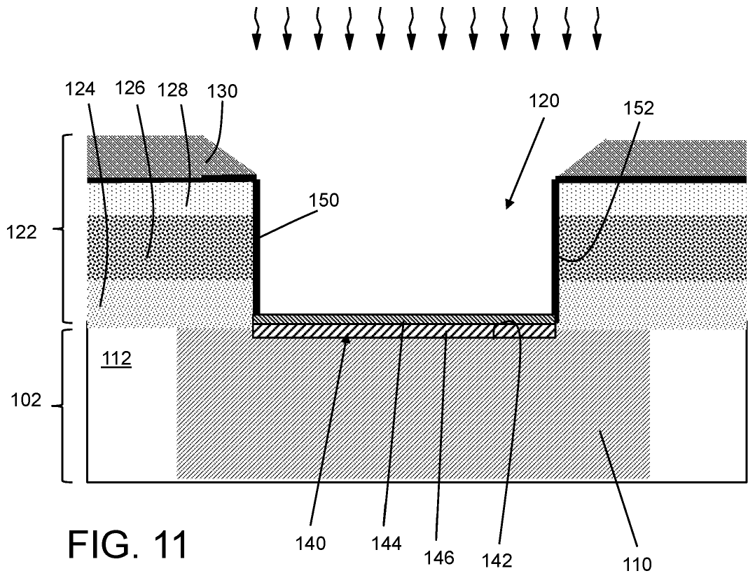

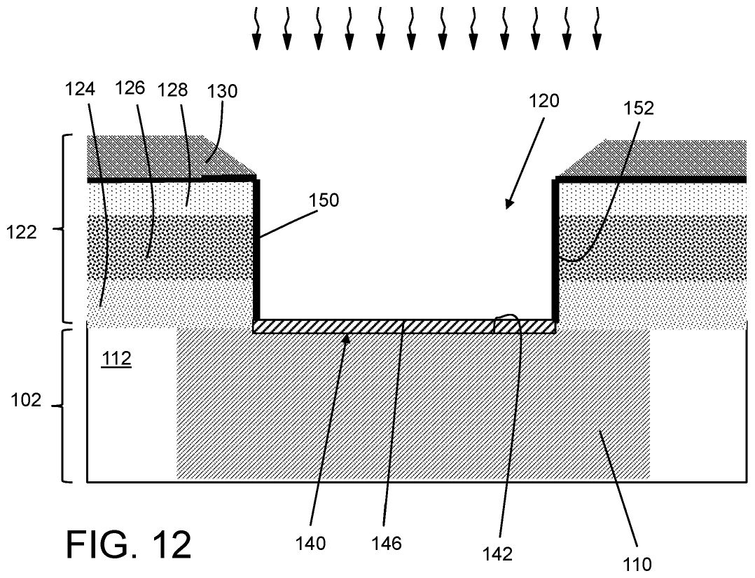

Referring to FIG. 11, in another embodiment, at least a portion of palladium layer 144 may diffuse into the copper of pad 110 to convert conductive layer 140 to include palladium layer 144 and copper palladium layer 146 (below palladium layer 144). This process may occur naturally due to the thinness of palladium layer 144. Alternatively, as also shown in FIG. 12, an annealing (i.e., heat treating—see curvy arrows) process may be performed after (initially) forming conductive layer 140. The annealing converts at least a portion of (initial) conductive layer 140 from palladium to a copper palladium alloy. FIG. 12 shows an embodiment in which all or mostly all of palladium layer 144 diffuses into the copper of pad 110 to convert conductive layer 140 to copper palladium layer 146. This process may occur naturally or through the annealing process. In FIGS. 11-12, it will be noted that the position of upper surface 142 of pad 110 may shift downwardly depending on the amount of diffusion.

FIG. 2B shows forming copper interconnect 114 directly on conductive layer 140 that now includes palladium layer 144 and copper palladium layer 146. Copper interconnect 114 includes a wire bond 160. This process can include the same processes as described relative to FIG. 2A. FIG. 2C shows forming copper interconnect 114 directly on conductive layer 140 that now includes only copper palladium layer 146. Copper interconnect 114 includes a wire bond 160. This process can include the same processes as described relative to FIG. 2A.

Embodiments of the disclosure provide various technical and commercial advantages, examples of which are discussed herein. Structure 100 provides higher temperature reliability by removing intermetallic compounds between pad 110 and copper interconnect 114 compared to conventional devices. Structure 100 also lowers costs because it does not require more expensive materials, like gold, silver or aluminum materials. As described, the process of making structure 100 is maskless and does not require any new equipment. Structure 100 can be used at any first level interconnection, e.g., wire bond, flip chip or copper pillar.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure, comprising:
a substrate;
a copper bond pad over the substrate;
a conductive layer in direct contact with an upper surface of the copper bond pad, the conductive layer consisting of palladium, copper palladium or both palladium and copper palladium; and
a copper interconnect in direct contact with the conductive layer.

2. The structure of claim 1, wherein the copper bond pad is defined at a bottom of an opening in at least one dielectric layer, and further comprising a passivation layer on sidewalls of the at least one dielectric layer above the copper bond pad.

3. The structure of claim 1, wherein the conductive layer consists of layers of both the palladium and the copper palladium.

4. The structure of claim 1, wherein the copper interconnect includes a copper wire bond in direct contact with the conductive layer.

5. The structure of claim 1, wherein the copper interconnect includes a copper redistribution layer (RDL) in direct contact with the conductive layer and a solder ball on the copper RDL.

6. The structure of claim 1, wherein only the conductive layer is between the copper interconnect and the copper bond pad.

7. The structure of claim 1, wherein the conductive layer has a thickness between 15 to 100 nanometers.

8. A method comprising:
exposing an upper surface of a copper bond pad;
forming a conductive layer directly on the exposed upper surface of the copper bond pad, the conductive layer consisting of palladium; and
forming a copper interconnect directly on the conductive layer.

9. The method of claim 8, wherein the conductive layer has a thickness between 15 to 100 nanometers.

10. The method of claim 8, further comprising cleaning the conductive layer prior to forming the copper interconnect.

11. The method of claim 10, wherein the cleaning includes performing a plasma etch using an etch chemistry including hydrogen in a ratio of 5% to 10% and a remaining portion including one of argon and nitrogen.

12. The method of claim 8, further comprising annealing after forming the conductive layer, the annealing converting at least a portion of the conductive layer from palladium to a copper palladium alloy.

13. The method of claim 8, wherein exposing the upper surface includes performing a plasma-based etching.

14. The method of claim 8, wherein forming the palladium layer includes electroless depositing the palladium layer.

15. The method of claim 8, wherein the copper interconnect forming includes forming one of: forming a copper wire bond on the copper bond pad; and forming a copper redistribution layer (RDL) and a solder ball on the copper RDL.

16. A method comprising:
exposing an upper surface of a copper bond pad at a bottom of an opening defined in at least one dielectric layer, wherein a passivation layer is on sidewalls of the opening above the copper bond pad;
forming a conductive layer directly on the exposed upper surface of the copper bond pad, the conductive layer consisting of palladium; and
forming a copper interconnect directly on the conductive layer.

17. The method of claim 16, wherein the conductive layer has a thickness between 15 to 100 nanometers.

18. The method of claim 16, further comprising cleaning the conductive layer prior to forming the copper interconnect.

19. The method of claim 16, further comprising annealing after forming the conductive layer, the annealing converting at least a portion of the conductive layer from palladium to a copper palladium alloy.

20. The method of claim 16, wherein the copper interconnect forming includes forming one of: a copper wire bond on the copper bond pad, and a copper redistribution layer (RDL) and a solder ball on the copper RDL.
